(19) United States
(12) Patent Application Publication
(10) Pub. No.: US 2025/0208503 A1
(43) Pub. Date: Jun. 26, 2025

(54) PHOTOSENSITIVE CONDUCTIVE PASTE, METHOD FOR PRODUCING LAMINATED ELECTRONIC COMPONENT, AND LAMINATED ELECTRONIC COMPONENT

(71) Applicant: Murata Manufacturing Co., Ltd., Kyoto-fu (JP)

(72) Inventors: Kenta KONDO, Nagaokakyo-shi (JP); Rikiya SANO, Nagaokakyo-shi (JP); Isamu MIYAKE, Nagaokakyo-shi (JP); Hiroyuki HONGOH, Nagaokakyo-shi (JP); Kouhei MURASATO, Nagaokakyo-shi (JP)

(73) Assignee: Murata Manufacturing Co., Ltd., Kyoto-fu (JP)

(21) Appl. No.: 18/988,456

(22) Filed: Dec. 19, 2024

(30) Foreign Application Priority Data
Dec. 21, 2023 (JP) 2023-215882

(51) Int. Cl. G03F 7/004; G03F 7/028; G03F 7/032

(52) U.S. Cl. CPC G03F 7/0047; G03F 7/028; G03F 7/0325

(57) ABSTRACT

A photosensitive conductive paste, a method for producing a laminated electronic component, and a laminated electronic component controlled in shrinkage behavior during firing are provided. A photosensitive conductive paste contains a conductive powder, an alkali-soluble polymer, a photosensitive monomer, a photopolymerization initiator, a solvent, and an organic flame retardant. Another photosensitive conductive paste contains a conductive powder, an organic component, and a solvent, and contains a cellulose derivative as the alkali-soluble polymer.

### CROSS-REFERENCE TO RELATED APPLICATION

This application claims benefit of priority to Japanese Patent Application No. 2023-215882, filed Dec. 21, 2022, the entire content of which is incorporated herein by reference.

### BACKGROUND

### Technical Field

The present disclosure relates to a photosensitive conductive paste, a method for producing a laminated electronic component, and a laminated electronic component.

### Background Art

In recent years, laminated electronic components such as a laminated ceramic circuit board have been produced by forming internal electrodes using a photosensitive conductive paste. The internal electrode is formed by firing a patterned photosensitive conductive paste to sinter a conductive powder contained in the photosensitive conductive paste. Examples of the photosensitive conductive paste used for a laminated electronic component include those disclosed in Japanese Patent Application Laid-Open No. 2002-169274 and Japanese Patent Application Laid-Open No. 2007-18884.

Japanese Patent Application Laid-Open No. 2002-169274 discloses a photosensitive conductive paste containing, as main components, 40 to 80 wt % of a conductive powder, 3 to 20 wt % of a photopolymerizable compound, 10 wt % or less of a photopolymerization initiator, and 0.3 to 2.5 wt % of one or more non-conductive metal oxides. The non-conductive metal oxide is generally called a “common material”. Japanese Patent Application Laid-Open No. 2002-169274 discloses that the contained common material can reduce the firing shrinkage of the internal electrode.

Japanese Patent Application Laid-Open No. 2007-18884 discloses a photosensitive conductive paste containing a first conductive powder obtained by an atomizing method and having an average particle diameter of 5 μm or less and a second conductive powder obtained by a wet reduction method and having an average particle diameter within a range of 0.2 to 2.0 μm at a weight ratio within a range of 20/80≤(first conductive powder/second conductive powder)≤80/20. Japanese Patent Application Laid-Open No. 2007-18884 discloses that the contained first conductive powder, which has a relatively larger average particle diameter, can reduce the firing shrinkage of the internal electrode.

### SUMMARY

However, it has been found that, when the firing shrinkage of the internal electrode is reduced but the shrinkage of the photosensitive conductive paste is not equivalent to the shrinkage of the element body material during firing, delamination can occur.

Therefore, the present disclosure provides a photosensitive conductive paste that is controlled in shrinkage behavior during firing. Further, the present disclosure provide a method for producing a laminated electronic component and a laminated electronic component using the photosensitive conductive paste.

A photosensitive conductive paste according to an aspect of the present disclosure contains a conductive powder, an organic component, and a solvent. The organic component includes an alkali-soluble polymer, a photosensitive monomer, a photopolymerization initiator, and an organic flame retardant.

A photosensitive conductive paste according to another aspect of the present disclosure contains a conductive powder, an organic component, and a solvent. The organic component includes an alkali-soluble polymer, a photosensitive monomer, and a photopolymerization initiator. Also, the photosensitive conductive paste contains a cellulose derivative as the alkali-soluble polymer.

According to the above embodiment, the photosensitive conductive paste is controlled in shrinkage behavior during firing. Therefore, when the photosensitive conductive paste is used as an internal electrode of a laminated electronic component, the difference in shrinkage behavior from the element body material becomes small during firing, and delamination is suppressed. In addition, since a common material is not an essential component and a conductive powder having a larger particle size is not necessarily required, resolution in photolithographic patterning is improved, and the formed internal electrode successfully has a reduced electric resistance.

According to the photosensitive conductive paste of the present disclosure, the photosensitive conductive paste is controlled in shrinkage behavior during firing.

### BRIEF DESCRIPTION OF THE DRAWINGS

FIG. 1 is a transparent perspective view schematically illustrating a laminated electronic component; and

FIG. 2 is an exploded perspective view schematically illustrating a laminated electronic component.

### DETAILED DESCRIPTION

Hereinafter, the photosensitive conductive paste, the method for producing a laminated electronic component, and the laminated electronic component of an embodiment of the present disclosure will be described in detail with reference to the illustrated embodiment. Note that the drawings include some schematic drawings and do not reflect actual dimensions or ratios in some cases.

### First Embodiment

### (Overall Configuration of Laminated Electronic Component)

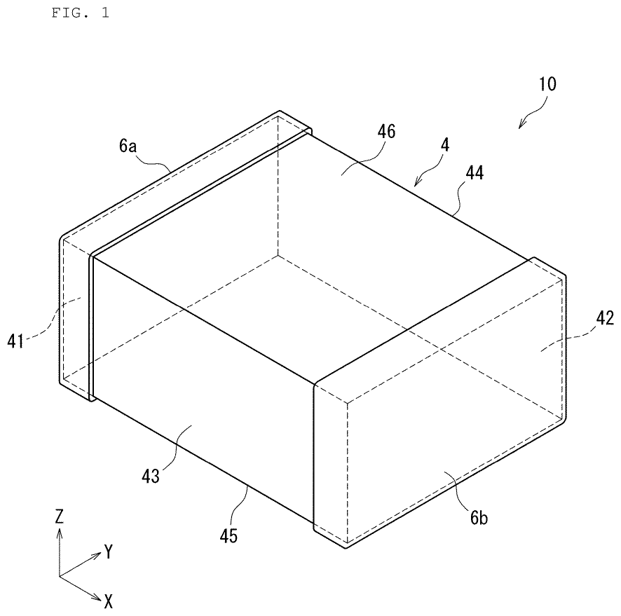

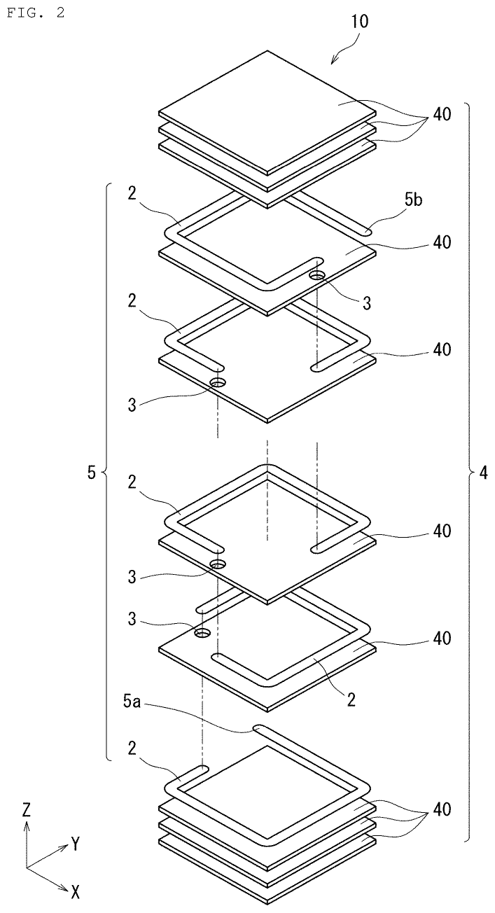

FIG. 1 is a transparent perspective view schematically illustrating a laminated electronic component. FIG. 2 is an exploded perspective view schematically illustrating a laminated electronic component. In FIG. 1, the element body is drawn transparently so that the structure can be easily understood, but may be translucent or opaque. In FIG. 1, the illustration of the coil is omitted so that the structure can be easily understood. In FIG. 2, the illustration of the external electrode is omitted in consideration of visibility.

Hereinafter, the laminated electronic component will be described with reference to a laminated coil component as an example. However, the laminated electronic component of the present disclosure is not limited to a laminated coil component, and can be applied to various laminated electronic components such as a laminated capacitor component and a laminated LC composite component.

As shown in FIGS. 1 and 2, a laminated electronic component 10 includes an element body 4, a coil 5 provided in the element body 4, and a first external electrode 6a and a second external electrode 6b provided on the element body 4. The coil 5 corresponds to the “internal electrode” described in the claims.

The shape of the element body 4 is not particularly limited, but is a substantially rectangular parallelepiped shape in this embodiment. The outer surface of the element body 4 includes a first end surface 41, a second end surface 42 facing the first end surface 41, a first side surface 43 connecting the first end surface 41 and the second end surface 42, a second side surface 44 facing the first side surface 43, a bottom surface 45 connecting the first end surface 41, the second end surface 42, the first side surface 43, and the second side surface 44, and a top surface 46 facing the bottom surface 45 and connected to the first end surface 41, the second end surface 42, the first side surface 43, and the second side surface 44. The direction from the first end surface 41 toward the second end surface 42 is defined as the X direction, the direction from the first side surface 43 toward the second side surface 44 is defined as the Y direction, and the direction from the bottom surface 45 toward the top surface 46 is defined as the Z direction. In this specification, the Z direction may be referred to as the upper side.

The element body 4 is configured by laminating a plurality of insulating layers 40. The insulating material of the insulating layer 40 is not particularly limited, and includes, for example, a borosilicate glass and an inorganic filler. The inorganic filler is, for example, a glass powder and a ceramic aggregate such as alumina. The stacking direction of the insulating layer 40 is parallel to the Z direction. That is, the insulating layer 40 is a layer extending in the XY plane. Among the plurality of coil wirings 2 to be described later, in the insulating layer 40 located between the adjacent coil wirings 2, a via hole 3 is provided at a position where the adjacent coil wirings 2 are connected. The via hole 3 penetrates the insulating layer 40 in the thickness direction (Z direction). In the present application, the term “parallel” is not limited to a strict parallel relationship, and includes a substantial parallel relationship in consideration of a realistic variation range. In the element body 4, the interface between the plurality of insulating layers 40 may be unclear due to firing or the like.

The first external electrode 6a and the second external electrode 6b are made of, for example, a conductive material such as Ag, Cu, Au, or an alloy containing these as a main component. In this embodiment, the first external electrode 6a is provided continuously to the entire surface of the first end surface 41 of the element body 4, the end portion of the first side surface 43 on the first end surface 41 side, the end portion of the second side surface 44 on the first end surface 41 side, the end portion of the bottom surface 45 on the first end surface 41 side, and the end portion of the top surface 46 on the first end surface 41 side. In addition, the second external electrode 6b is provided continuously to the entire surface of the second end surface 42 of the element body 4, the end portion of the first side surface 43 on the second end surface 42 side, the end portion of the second side surface 44 on the second end surface 42 side, the end portion of the bottom surface 45 on the second end surface 42 side, and the end portion of the top surface 46 on the second end surface 42 side. In short, each of the first external electrode 6a and the second external electrode 6b is a five-face electrode. However, the present disclosure is not limited thereto, and the first external electrode 6a may be, for example, an L-shaped electrode provided continuously on a part of the first end surface 41 and a part of the bottom surface 45. Similarly, the second external electrode 6b may be, for example, an L-shaped electrode provided continuously on a part of the second end surface 42 and a part of the bottom surface 45.

The coil 5 is, for example, a sintered body of the photosensitive conductive paste containing a conductive powder such as Ag or Cu. The coil 5 is spirally wound along the stacking direction of the insulating layer 40. The first end 5a of the coil 5 is exposed from the first end surface 41 of the element body 4 and connected to the first external electrode 6a. The second end 5b of the coil 5 is exposed from the second end surface 42 of the element body 4 and connected to the second external electrode 6b.

The coil 5 is formed in a rectangular shape when viewed from the axial direction, but is not limited to this shape. The shape of the coil 5 may be, for example, a circular shape, an elliptical shape, a rectangular shape, or another polygonal shape. The axial direction of the coil 5 is parallel to the Z direction, and the coil 5 is wound along the axial direction. The axis of the coil 5 means the central axis of the spiral shape of the coil 5.

The coil 5 includes a plurality of coil wirings 2 laminated along the axial direction and via wirings (not illustrated) extending along the axial direction and connecting the coil wirings 2 adjacent to each other in the axial direction. The plurality of coil wirings 2 is each wound along a plane, arranged side by side in the axial direction, and forms a spiral while being electrically connected in series.

The coil wiring 2 is formed by being wound on the main surface (XY plane) of the insulating layer 40 orthogonal to the axial direction. The number of winds of the coil wiring 2 is less than one, but may be one or more. The via wiring is provided in the via hole 3 of the insulating layer 40 and penetrates the insulating layer 40 in the thickness direction (Z direction). The coil wirings 2 adjacent to each other in the stacking direction are electrically connected in series through the via wiring.

In such a laminated electronic component 10, a plurality of insulating layers 40 and patterning layers of the photosensitive conductive paste is alternately laminated, and each of the plurality of insulating layers 40 and the plurality of patterning layers of the photosensitive conductive paste is sintered. As a result, the element body 4 is formed from the plurality of insulating layers 40, and the coil 5 is formed from the plurality of patterning layers of the photosensitive conductive paste.

### (Detailed Configuration of Photosensitive Conductive Paste)

Next, the detailed configuration of the photosensitive conductive paste used for forming the coil 5 will be described. Hereinafter, the photosensitive conductive paste used for forming the coil 5 of the laminated electronic component 10, which is a laminated coil component, will be described. However, the photosensitive conductive paste of the present disclosure is not limited thereto, and can be used for forming an internal electrode of various laminated electronic components such as a laminated capacitor component and a laminated LC composite component. For example, in a laminated capacitor component, the photosensitive conductive paste of the present disclosure can be used for forming a capacitor electrode.

The photosensitive conductive paste contains a conductive powder, an organic component, and a solvent.

### <Conductive Powder>

The conductive powder is sintered by firing to become the conductor of the coil 5. The type of the conductive powder is not particularly limited, but may be silver (Ag) or copper (Cu) in order to reduce the electric resistance of the coil 5 to be formed. The content of the conductive powder may be 65 wt % or more and 90 wt % or less (i.e., from 65 wt % to 90 wt %) with respect to the photosensitive conductive paste. From the viewpoint of suppressing shrinkage of the photosensitive conductive paste after firing, the content of the conductive powder may be 70 wt % or more and 85 wt % or less (i.e., from 70 wt % to 85 wt %) with respect to the photosensitive conductive paste.

The average particle diameter D50 (median diameter) of the conductive powder may be 0.5 μm or more and 5.0 μm or less (i.e., from 0.5 μm to 5.0 μm) from the viewpoint of forming a fine pattern of the coil 5. The average particle diameter D50 is a 50% particle diameter in a volume-based particle size distribution measured by a laser diffraction particle size distribution measuring apparatus (for example, MT3000, manufactured by MicrotracBEL Corp.).

The conductive powder may be a silver (Ag) powder. The average particle diameter D50 of the Ag powder may also be 0.5 μm or more and 5.0 μm or less (i.e., from 0.5 μm to 5.0 m). In particular, the conductive powder may be an atomized Ag powder, which is produced by an atomization process. The atomized Ag powder has a larger conductive powder crystallite diameter and less organic impurities than an Ag powder produced by a wet reduction method. Therefore, the electric resistance of the formed coil 5 is further reduced.

### <Organic Component>

The organic component includes at least an alkali-soluble polymer, a photosensitive monomer, a photopolymerization initiator, and an organic flame retardant. The content of the organic component may be 5 wt % or more and 8 wt % or more with respect to the photosensitive conductive paste. The content of the organic component may be 20 wt % or less and 15 wt % or less with respect to the photosensitive conductive paste.

The organic component is decomposed by heating. The weight loss of the organic component (in this case, has the same meaning as volume reduction) causes shrinkage of the coil 5. However, when the shrinkage behavior of the photosensitive conductive paste and the shrinkage behavior of the element body material are equivalent with each other during firing, it is possible to suppress peeling between layers called delamination, which is a structural defect that can occur between the coil 5 and the element body 4 to be obtained.

The element body material typically contains a borosilicate glass, and the softening point thereof is usually higher than 700° C. When the glass component is softened by heating at higher than 700° C., the element body material is rapidly sintered, and is quenched. That is, the element body material exhibits a shrinkage behavior in which the shrinkage is small until the glass component is softened, and the shrinkage is rapid after the glass component is softened.

The photosensitive conductive paste according to the present disclosure contains an organic flame retardant. Therefore, the decomposition rate of the organic component is reduced, and the shrinkage of the photosensitive conductive paste slowly proceeds during firing. As described above, the element body material also has small shrinkage until the glass component is softened. That is, shrinkage of both the photosensitive conductive paste and the element body material at the beginning when firing is started is small, and the shrinkage behaviors of both are equivalent with each other.

On the other hand, the organic flame retardant is also decomposed by heating similarly to other organic components. Therefore, when the decomposition temperature of the organic component is reached, the role of the organic flame retardant is terminated, and the organic component is rapidly decomposed. That is, in the latter half of the firing stage, decomposition of the organic component rapidly proceeds, and shrinkage of the photosensitive conductive paste occurs. As described above, the shrinkage behavior of the element body material and the shrinkage behavior of the photosensitive conductive paste correspond to each other also in the latter half of the firing stage. Accordingly, it can be expected that delamination is suppressed.

The organic flame retardant does not contain a metal atom. Therefore, the influence on the characteristics (in particular, electrical resistance) of the coil 5 to be obtained is small. When the flame retardant contains a metal atom, the flame retardant may remain in the coil 5 as a metal oxide after firing. The metal oxide is typically non-conductive and, like the common material, may increase the electrical resistance of the coil 5.

In the cured product (hereinafter, referred to as “first cured product”) of the organic component used for the photosensitive conductive paste according to the present disclosure, the thermal decomposition ability in an oxygen atmosphere can satisfy a condition A and a condition B below.

### (Condition A)

In thermogravimetry, there is a weight loss rate of less than 50% at 300° C.

### (Condition B)

In thermogravimetry, there is a weight loss rate of 100% at 700° C.

The condition A indicates that the degree of thermal decomposition of the cured product is small up to 300° C. That is, the condition A means that the shrinkage rate of the photosensitive conductive paste is small up to 300° C. Up to the temperature of 300° C., shrinkage of the element body material is also small as described above. That is, up to 300° C., shrinkage of both the photosensitive conductive paste and the element body material is small, and the shrinkage behaviors of both are equivalent with each other. The weight loss rate (hereinafter, may be referred to as ΔTG) of the cured product at 300° C. may be less than 40%, less than 35%, or less than 30%.

However, it is desirable that the thermal decomposition of the organic component contained in the photosensitive conductive paste is completed before the glass component of the element body material starts to soften. When the organic component remains at the start of softening the glass component of the element body material, the decomposed and gasified organic component is confined by the molten glass component. A gaseous organic component remaining inside the laminated electronic component 10 may also contribute to delamination.

The condition B indicates that the decomposition of the first cured product is completed up to 700° C. When the temperature exceeds 700° C., the glass component of the element body material starts to soften as described above. When the decomposition of the first cured product is completed up to 700° C., it is possible to suppress confinement of the gasified organic component as described above. The first cured product may have a weight loss rate of 100% at 600° C.

When both of the condition A and the condition B are satisfied, the organic component contained in the photosensitive conductive paste is slowly decomposed up to 300° C., and the decomposition is completed between higher than 300° C. and 700° C. (the weight loss rate becomes 100%). That is, since the shrinkage behavior of the element body material and the shrinkage behavior of the photosensitive conductive paste are equivalent with each other during firing, it can be expected that delamination is suppressed.

The first cured product is obtained by mixing each organic component at a blending ratio in the photosensitive conductive paste, followed by curing. The first cured product may be obtained by mixing a photosensitive monomer, an alkali-soluble polymer, a photopolymerization initiator, and an organic flame retardant at a blending ratio in the photosensitive conductive paste, followed by curing the obtained first mixture. This is because the blending amount of other organic components (typically, the additives described below) is small, and the influence on ΔTG is small.

In the first mixture, the content of the photosensitive monomer is, for example, 30 wt % or more and 60 wt % or less (i.e., from 30 wt % to 60 wt %). In the first mixture, the content of the alkali-soluble polymer is, for example, 30 wt % or more and 60 wt % or less (i.e., from 30 wt % to 60 wt %). In the first mixture, the content of the photopolymerization initiator is, for example, 3 wt % or more and 10 wt % or less (i.e., from 3 wt % to 10 wt %). In the first mixture, the content of the organic flame retardant is, for example, 1 wt % or more and 30 wt % or less (i.e., from 1 wt % to 30 wt %).

The thermal decomposition ability of the first cured product in an oxygen atmosphere may further satisfy a condition C below.

### (Condition C)

In thermogravimetry, there is a weight loss rate change of 70% or less in a range of 300° C. or higher and 400° C. or lower (i.e., from 300° C. to 400° C.).

The condition C indicates that the weight of the first cured product decreases constantly and slowly at higher than 300° C. The condition C means that shrinkage of the photosensitive conductive paste progresses slowly until degreasing is completed. Since the shrinkage behavior is further equivalent with the shrinkage behavior of the element body material during firing, it can be expected that delamination is further suppressed.

The weight loss rate change in the range of 300° C. or higher and 400° C. or lower (i.e., from 300° C. to 400° C.) is the difference between the weight loss rate ΔTG₃₀₀ of the first cured product at 300° C. and the weight loss rate ΔTG₄₀₀ of the first cured product at 400° C. (|ΔTG₄₀₀−ΔTG₃₀₀|).

### <<Alkali-Soluble Polymer>>

The alkali-soluble polymer is neutralized with a basic compound to be solubilized. The alkali-soluble polymer is removed together with the uncured photosensitive monomer, the conductive powder, and the like, for example, in development processing using an alkaline developer. On the other hand, when the photosensitive monomer is polymerized by active energy rays, the alkali-soluble polymer present in the vicinity forms a film together with a polymer of the photosensitive monomer, and forms, for example, a part of the internal electrode pattern. As a result, the adhesion of the internal electrode pattern to the insulating layer can be improved.

The content of the alkali-soluble polymer may be 30 wt % or more or 35 wt % or more with respect to the organic component. The content of the alkali-soluble polymer may be 60 wt % or less or 55 wt % or less with respect to the organic component.

The photosensitive conductive paste may contain one kind of the alkali-soluble polymer or two or more kinds of the alkali-soluble polymers.

The alkali-soluble polymer has at least one acid group in the side chain. The acid group typically includes a carboxy group. For example, the alkali-soluble polymer includes, as a main chain, a polymer chain having at least one of a carbon-carbon bond, an ether bond, a urea bond, an ester bond, and a urethane bond. From the viewpoint of transparency, the main chain of the alkali-soluble polymer may contain a polymer chain having a carbon-carbon bond.

An alkali-soluble polymer having at least one carboxy group in the side chain and including a polymer chain having a carbon-carbon bond as a main chain is obtained, for example, by copolymerizing an unsaturated carboxylic acid and an ethylenically unsaturated compound. The alkali-soluble polymer typically includes a carboxy group-containing acrylic polymer.

Examples of the unsaturated carboxylic acid include acrylic acid, methacrylic acid, crotonic acid, maleic acid, fumaric acid, itaconic acid, vinylacetic acid, and dimers and anhydrides thereof. These are used singly or in combination of two or more kinds thereof.

Examples of the ethylenically unsaturated compound include acrylic acid esters such as methyl acrylate, ethyl acrylate, butyl acrylate, isobutyl acrylate, t-butyl acrylate, 2-ethylhexyl acrylate, lauryl acrylate, and isoboronyl acrylate; methacrylic acid esters such as methyl methacrylate, ethyl methacrylate, butyl methacrylate, isobutyl methacrylate, t-butyl methacrylate, 2-ethylhexyl methacrylate, lauryl methacrylate, and isoboronyl methacrylate; fumaric acid esters such as monoethyl fumarate; and styrene. These are used singly or in combination of two or more kinds thereof.

The carboxy group of the alkali-soluble polymer may be introduced after the main chain is formed. The carboxy group of the alkali-soluble polymer may be introduced, for example, by reacting an unsaturated monocarboxylic acid with a compound having an epoxy group in a side chain and having the above-described polymer chain, and then further reacting a saturated or unsaturated polycarboxylic anhydride.

The alkali-soluble polymer may have an unsaturated bond. The unsaturated bond of the alkali-soluble polymer may be introduced, for example, by subjecting the carboxyl group on the side chain to addition with a monomer being reactive thereto and having a polymerizable functional group (typically, an epoxy group).

The weight average molecular weight (Mw) of the alkali-soluble polymer may be 5,000 or more and 50,000 or less (i.e., from 5,000 to 50,000). The acid value of the alkali-soluble polymer may be 30 mgKOH/g or more and 150 mgKOH/g or less (i.e., from 30 mgKOH/g to 150 mgKOH/g).

### <<Photosensitive Monomer>>

The photosensitive monomer reacts with the photopolymerization initiator to generate monomer radicals. The monomer radicals polymerize to form a polymer. The content of the photosensitive monomer may be 30 wt % or more or 35 wt % or more with respect to the organic component. The content of the photosensitive monomer may be 60 wt % or less or 50 wt % or less with respect to the organic component.

The photosensitive conductive paste may contain one photosensitive monomer or two or more photosensitive monomers.

The photosensitive monomer is not limited as long as it has at least one reactive group to involve a radical reaction. Examples of the radical reactive group include at least one selected from the group consisting of an acrylamide group, an acryloyl group, a methacryloyl group, an allyl group, a vinyl group, a styryl group, and a mercapto group. The photosensitive monomer may have at least one (meth) acryloyl group as the radical reactive group. The “(meth) acryloyl group” represents an acryloyl group and/or a methacryloyl group.

Examples of the photosensitive monomer having a (meth) acryloyl group include: monofunctional (meth) acrylate monomers such as stearyl (meth) acrylate, tetrahydrofurfuryl (meth) acrylate, lauryl (meth) acrylate, 2-phenoxyethyl (meth) acrylate, isodecyl (meth) acrylate, isooctyl (meth) acrylate, tridecyl (meth) acrylate, caprolactone (meth) acrylate, and ethoxylated nonylphenol (meth) acrylate; bifunctional (meth) acrylate monomers such as tripropylene glycol di (meth) acrylate, isocyanuric acid EO-modified diacrylate, 1,3-butanediol di (meth) acrylate, 1,4-butanediol di (meth) acrylate, diethylene glycol di (meth) acrylate, tetraethylene glycol di (meth) acrylate, triethylene glycol di (meth) acrylate, ethoxylated bisphenol A di (meth) acrylate, and propoxylated neopentyl glycol di (meth) acrylate; trifunctional (meth) acrylate monomers such as glycerin tri (meth) acrylate, trimethylolpropane tri (meth) acrylate, ethoxylated trimethylolpropane tri (meth) acrylate, propoxylated trimethylolpropane tri (meth) acrylate, propoxylated glyceryl tri (meth) acrylate, pentaerythritol tri (meth) acrylate, dipentaerythritol tri (meth) acrylate, ethoxylated pentaerythritol tri (meth) acrylate, tris (2-hydroxyethyl) isocyanurate tri (meth) acrylate, caprolactone-modified tris (2-hydroxyethyl) isocyanurate tri (meth) acrylate, hexanediol tri (meth) acrylate, tripropylene glycol tri (meth) acrylate, trimethylolpropane tri (meth) acrylate, and EO-modified trimethylolpropane tri (meth) acrylate; tetrafunctional (meth) acrylate monomers such as pentaerythritol tetra (meth) acrylate, dipentaerythritol tetra (meth) acrylate, tripentaerythritol tetra (meth) acrylate, ditrimethylolpropane tetra (meth) acrylate, and ethoxylated pentaerythritol tetra (meth) acrylate; pentafunctional (meth) acrylate monomers such as dipentaerythritol penta (meth) acrylate, tripentaerythritol penta (meth) acrylate, and dipentaerythritol monohydroxypenta (meth) acrylate; hexafunctional (meth) acrylate monomers such as dipentaerythritol hexa (meth) acrylate, caprolactone-modified dipentaerythritol hexa (meth) acrylate, and tripentaerythritol hexa (meth) acrylate; and hepta- or higher functional (meth) acrylate monomers such as tripentaerythritol hepta (meth) acrylate and tripentaerythritol octa (meth) acrylate. These are used singly or in combination of two or more kinds thereof.

The photosensitive monomer may be a tri- or higher functional (meth) acrylate monomer, a tetra- or higher functional (meth) acrylate monomer, or a penta- or higher functional (meth) acrylate monomer. The photosensitive monomer may be dipentaerythritol monohydroxypenta (meth) acrylate.

### <<Photopolymerization Initiator>>

The photopolymerization initiator generates highly reactive radicals by active energy rays. The radicals are added to the photosensitive monomer to cause an initiation reaction of the photosensitive monomer. The radicals are generated in a chain manner, and in due course, a polymer derived from the photosensitive monomer is generated. The content of the photopolymerization initiator may be 3 wt % or more or 5 wt % or more with respect to the organic component. The content of the photopolymerization initiator may be 10 wt % or less or 8 wt % or less with respect to the organic component.

Examples of the photopolymerization initiator include at least one selected from the group consisting of a benzoin- or benzoin ether-based compound, an alkylphenone-based compound, a benzophenone-based compound, an oxime ester-based compound, an acylphosphine oxide compound, and an α-ketoester-based compound. The photopolymerization initiator may be an alkylphenone-based compound, may be an α-aminoalkylphenone-based compound, and may be 2-methyl-1-(4-methylthiophenyl)-2-morpholinopropane-1-one.

### <<Organic Flame Retardant>>

The organic flame retardant is a flame retardant containing no metal atom. By the organic flame retardant, the shrinkage behavior of the photosensitive conductive paste during firing is controlled, and delamination between the element body 4 and the coil 5 is suppressed.

The content of the organic flame retardant may be 3 wt % or more, and may be 5 wt % or more with respect to the organic component. The content of the organic flame retardant may be 20 wt % or less, may be 15 wt % or less, and may be 10 wt % or less with respect to the organic component.

The organic flame retardant may be at least one selected from the group consisting of a phosphoric acid ester compound, a thioether compound, a nitrogen-containing aromatic compound, a brominated hydrocarbon compound, and a chlorinated hydrocarbon compound. The organic flame retardant may be at least one of a thioether compound and a chlorinated hydrocarbon compound.

Examples of the phosphoric acid ester compound include phosphoric acid esters such as triphenyl phosphate (TPP), tricresyl phosphate (TCP), trixylenyl phosphate (TXP), trimethyl phosphate (TMP), triethyl phosphate (TEP), cresyl diphenyl phosphate (CDP), cresyl di 2,6-xylenyl phosphate, and triallyl phosphate (IPPP); aromatic condensed phosphoric acid esters such as 1,3-phenylenebis(diphenyl phosphate), 1,3-phenylenebis(dixylenyl)phosphate, resorcinol bis(diphenyl)phosphate, and bisphenol A bis(diphenyl phosphate); halogen-containingphosphoric acid esters such as tris(dichloropropyl)phosphate, tris(p-chloropropyl)phosphate, and tris(chloroethyl)phosphate; and halogen-containing condensed phosphoric acid esters such as 2,2-bis(chloromethyl)trimethylene bis(bis(2-chloroethyl)phosphate), and polyoxyalkylene bisdichloroalkyl phosphate. These are used singly or in combination of two or more kinds thereof.

Examples of the thioether compound include dilauryl thiodipropionate, ditridecyl thiodipropionate, dimyristyl thiodipropionate, distearyl thiodipropionate, pentaerythritol-tetrakis(3-lauryl thiopropionate), pentaerythritol-tetrakis(3-dodecyl thiopropionate), pentaerythritol-tetrakis(3-octadecyl thiopropionate), pentaerythritol tetrakis(3-myristyl thiopropionate), and pentaerythritol-tetrakis(3-stearyl thiopropionate). These are used singly or in combination of two or more kinds thereof.

Examples of the nitrogen-containing aromatic compound include a melamine compound, a triazine compound, and a guanidine compound. Specific examples of the nitrogen-containing aromatic compound include trichlorotriazine, piperazine, melamine cyanurate, and a reaction product of a melamine-based compound and polyphosphoric acid. These are used singly or in combination of two or more kinds thereof.

Examples of the brominated hydrocarbon compound include hexabromocyclododecane, tetrabromocyclooctane, hexabromobenzene, pentabromodiphenyl ether, octabromodiphenyl ether, decabromodiphenyl ether, tetrabromobisphenol A (TBBA), TBBA-epoxy oligomer, TBBA-polycarbonate oligomer, TBBA-bis(dibromopropyl ether), TBBA-bis(aryl ether), 1,2-bis(2,4,6-tribromophenoxy)ethane, 2,4,6-tris(2,4,6-tribromophenoxy)-1,3,5-triazine, 2,6-dibromophenol, 2,4-dibromophenol, brominated polystyrene, and ethylene bistetrabromophthalimide. These are used singly or in combination of two or more kinds thereof.

Examples of the chlorinated hydrocarbon compound include chlorinated paraffin, 1,6,7,8,9,14,15,16,17,17,18,18-dodecachloropentacyclo[12.2.1.16,9.02,13.05,10]octadeca-7,15-diene, and chlorinated polyethylene. These are used singly or in combination of two or more kinds thereof.

The organic component may further contain additives such as a sensitizer, an antifoaming agent, an anti-settling agent, and a dispersant.

### <Solvent>

The solvent is not particularly limited, and examples thereof include ethylene glycol monobutyl ether, ethylene glycol monohexyl ether, ethylene glycol monoethylhexyl ether, propylene glycol monobutyl ether, dipropylene glycol monoethyl ether, dipropylene glycol monobutyl ether, propylene glycol monophenyl ether, ethyl acetate, butyl acetate, pentyl acetate, hexyl acetate, and cyclohexanol acetate. These are used singly or in combination of two or more kinds thereof.

The content of the solvent may be 3 wt % or more, and may be 5 wt % or more, with respect to the photosensitive conductive paste. The content of the solvent may be 20 wt % or less, and may be 15 wt % or less, with respect to the photosensitive conductive paste.

### <Metal Resinate>

The photosensitive conductive paste may contain a metal resinate. The resinate is a metal resinate containing a metal having a melting point higher than the melting point of the conductive powder. Examples of the metal contained in the metal resinate include Rh, Ni, Cu, Mn, and Zr. Examples of such a metal resinate include metal octylates, metal naphthenates, metal 2-ethylhexanoates, metal sulfonates, metal mercaptides, and alkoxy metal compounds.

### <Common Material>

The photosensitive conductive paste may contain a common material (non-conductive metal oxide), but the content thereof is preferably as small as possible from the viewpoint of improving resolution during photolithographic patterning and reducing electric resistance. The content of the common material may be 3.0 wt % or less, 1.0 wt % or less, or 0 wt %, with respect to the photosensitive conductive paste.

### (Method for Producing Laminated Electronic Component)

Next, the method for producing the laminated electronic component 10 will be described. The method for producing the laminated electronic component 10 includes a step of laminating the photosensitive conductive paste on the insulating layer 40; and a step of sintering the photosensitive conductive paste and the insulating layer 40 at a firing temperature of 800° C. or higher. The coil 5 (internal electrode) is formed from the photosensitive conductive paste, the element body 4 is formed from the insulating layer 40, and the coil 5 is provided in the element body 4.

According to the above production method, the shrinkage behavior of the photosensitive conductive paste can be equivalent with the shrinkage behavior of the element body material during firing. Therefore, it can be expected that delamination is suppressed.

Hereinafter, an example of the method for producing the laminated electronic component 10 using the photosensitive conductive paste of the present disclosure will be specifically described.

As shown in FIG. 2, a glass paste as an insulating paste is screen-printed and dried on a support film such as a PET film, and this process is repeated several times to obtain the insulating layer (glass layer) 40 having a predetermined thickness (for example, about 100 μm). In FIG. 2, the support film is omitted.

The insulating paste such as a glass paste contains an insulating inorganic component and an organic component. The glass paste contains, for example, a glass powder and a ceramic aggregate (inorganic filler) as the insulating inorganic component, and contains, for example, an acrylic polymer as the organic component. In addition, a solvent, a dispersant, an antifoaming agent, and the like may be contained as the organic component.

The kind of the glass powder contained in the insulating paste is not particularly limited, and for example, SiO₂—B₂O₃—K₂O-based glass containing SiO₂, B₂O₃, and K₂O at a predetermined ratio can be used. Two or more kinds of glass powders may be mixed and used. The average particle diameter of the glass powder is not particularly limited, but may be 0.1 m or more and 5.0 μm or less (i.e., from 0.1 μm to 5.0 μm).

The type of the ceramic aggregate contained in the insulating paste is not particularly limited, and for example, alumina can be used. Two or more kinds of ceramic aggregates may be mixed and used. The average particle diameter of the ceramic aggregate is not particularly limited, but may be 0.1 μm or more and 5.0 μm or less (i.e., from 0.1 μm to 5.0 μm).

The insulating layer 40 may be prepared by laminating green sheets formed in a sheet shape in advance.

The photosensitive conductive paste of the present disclosure is screen-printed on the insulating layer 40 so that the photosensitive conductive paste has a film thickness of about 5 m or more and 20 μm or less (i.e., from 5 μm to 20 μm), dried, and then selectively exposed and developed to form the coil wiring 2 of the first layer.

The glass paste is screen-printed on the entire surface from above the coil wiring 2 of the first layer so that the glass paste has a film thickness of about 10 to 20 μm, and dried. Subsequently, the via hole 3 is formed at a predetermined position of the insulating layer 40 formed on the coil wiring 2 of the first layer. The via hole 3 is formed by, for example, laser processing or pattern printing, or when the insulating paste has photolithographic characteristics, by a patterning method.

Again, the photosensitive conductive paste of the present disclosure is screen-printed on the entire surface so that the photosensitive conductive paste has a film thickness of about 5 μm or more and 10 μm or less (i.e., from 5 μm to 10 μm), dried, and then selectively exposed and developed to form the coil wiring 2 of the second layer.

The lamination of the insulating layer 40 and the coil wiring 2 is repeated until a desired number of layers is obtained.

Further, the entire surface printing of the glass paste and drying are repeated a required number of times to form the insulating layer 40 on the coil wiring 2 of the uppermost layer. As a result, a laminated structure formed by interlayer-connecting the coil wirings 2 through the via holes 3 is obtained.

The obtained laminated structure is divided into chip shapes using a dicer, and then the support film such as a PET film is separated. Thereafter, firing is performed at a temperature of 800° C. or higher. By this firing, the photosensitive conductive paste is sintered to form the coil 5. Further, the insulating layer 40 is sintered to form the element body 4.

The first external electrode 6a and the second external electrode 6b are formed on the fired laminate. Furthermore, by an electrolytic plating method, an electroless plating method, or the like, a plating layer having a single layer or a laminated structure may be deposited on the outer surface of the first external electrode 6a and the second external electrode 6b.

As described above, the laminated electronic component 10 illustrated in FIG. 1 is obtained.

### Second Embodiment

A second embodiment is different from the first embodiment in that the photosensitive conductive paste contains no organic flame retardant and contains a cellulose derivative as an alkali-soluble polymer. This different configuration will be described below. Other configurations of the second embodiment are the same as those of the first embodiment, and omitted from description. In the second embodiment, the configuration of the electronic component and the method for producing an electronic component are the same as those in the first embodiment, and omitted from description.

In the present embodiment, a cellulose derivative is contained as an alkali-soluble polymer. The cellulose derivative is less likely to be thermally decomposed than other alkali-soluble polymers (typically, a carboxy group-containing acrylic polymer). As a result, the decomposition rate of the organic component is reduced, and the shrinkage of the photosensitive conductive paste slowly proceeds at the beginning when firing is started. As described above, the element body material also has small shrinkage until the glass component is softened. That is, shrinkage of both the photosensitive conductive paste and the element body material at the beginning when firing is started is small, and the shrinkage behaviors of both are equivalent with each other.

On the other hand, the cellulose derivative is also decomposed by heating similarly to other organic components. Therefore, when the decomposition temperature of the organic component is reached, the organic component including the cellulose derivative is rapidly decomposed. That is, in the latter half of the firing stage, decomposition of the organic component rapidly proceeds, and shrinkage of the photosensitive conductive paste occurs. As described above, the shrinkage behavior of the element body material and the shrinkage behavior of the photosensitive conductive paste correspond to each other also in the latter half of the firing stage. Accordingly, it can be expected that delamination is suppressed.

In the cured product (hereinafter, referred to as “second cured product”) of the organic component used for the photosensitive conductive paste according to the present disclosure, the thermal decomposition ability in an oxygen atmosphere can satisfy the above condition A and condition B.

The thermal decomposition ability of the second cured product in an oxygen atmosphere may further satisfy the above condition C.

The second cured product is obtained by mixing each organic component at a blending ratio in the photosensitive conductive paste, followed by curing. Similarly to the above, the second cured product may be obtained by mixing a photosensitive monomer, an alkali-soluble polymer containing a cellulose derivative, and a photopolymerization initiator at a blending ratio in the photosensitive conductive paste, followed by curing the obtained second mixture.

In the second cured product, the content of the photosensitive monomer is, for example, 30 wt % or more and 60 wt % or less (i.e., from 30 wt % to 60 wt %). In the second cured product, the content of the alkali-soluble polymer containing a cellulose derivative is, for example, 30 wt % or more and 60 wt % or less (i.e., from 30 wt % to 60 wt %). In the second cured product, the content of the photopolymerization initiator is, for example, 3 wt % or more and 10 wt % or less (i.e., from 3 wt % to 10 wt %).

The cellulose derivative may have a water-soluble substituent. Examples of the water-soluble substituent include at least one selected from the group consisting of a hydroxyalkyl group, a carboxyalkyl group, a phthalic acid group, a sulfuric acid group, and a phosphoric acid group. Among them, from the viewpoint of high alkali solubility, at least one of a hydroxyalkyl group and a carboxyalkyl group may be used.

Examples of the cellulose derivative having a water-soluble substituent include hydroxyethyl cellulose, hydroxyethyl methyl cellulose, hydroxypropyl cellulose, ethyl hydroxyethyl cellulose, hydroxyethyl carboxymethyl cellulose, hydroxypropyl methyl cellulose, hydroxymethyl cellulose phthalate, hydroxypropyl methyl cellulose phthalate, hydroxypropyl methyl cellulose acetate phthalate, carboxymethyl cellulose, carboxymethyl ethyl cellulose, and hydroxypropyl methyl cellulose. These are used singly or in combination of two or more kinds thereof.

The weight ratio of the cellulose derivative occupied in the alkali-soluble polymer may be, for example, 5 wt % or more and 100 wt % or less (i.e., from 5 wt % to 100 wt %). As a result, the effect of reducing the decomposition rate of the organic component is easily exhibited. The weight ratio of the cellulose derivative occupied in the alkali-soluble polymer may be 20 wt % or more and may be 40 wt % or more. The weight ratio of the cellulose derivative occupied in the alkali-soluble polymer may be 100 wt %, may be 90 wt % or less, and may be 80 wt % or less.

### Third Embodiment

A third embodiment is different from the first embodiment in that a cellulose derivative is contained as an alkali-soluble polymer. This different configuration will be described below. Other configurations of the third embodiment are the same as those of the first embodiment, and omitted from description. In the third embodiment, the configuration of the electronic component and the method for producing an electronic component are the same as those in the first embodiment, and omitted from description.

In the present embodiment, the photosensitive conductive paste contains a cellulose derivative as an alkali-soluble polymer together with an organic flame retardant. As a result, the decomposition rate of the organic component is further easily reduced. The content of the organic flame retardant is the same as that in the first embodiment. The weight ratio of the cellulose derivative occupied in the alkali-soluble polymer is the same as that in the second embodiment. Examples of the cellulose derivative include those that are the same as in the second embodiment.

Also in this case, in the cured product (hereinafter, referred to as “third cured product”) of the organic component (a photosensitive monomer, an alkali-soluble polymer including a cellulose derivative, a photopolymerization initiator, and an organic flame retardant) used for the photosensitive conductive paste according to the present disclosure, the thermal decomposition ability in an oxygen atmosphere can satisfy the above condition A and condition B.

The thermal decomposition ability of the third cured product in an oxygen atmosphere may further satisfy the above condition C.

The third cured product is obtained by mixing each organic component at a blending ratio in the photosensitive conductive paste, followed by curing. Similarly to the above, the third cured product may be obtained by mixing a photosensitive monomer, an alkali-soluble polymer containing a cellulose derivative, a photopolymerization initiator, and an organic flame retardant at a blending ratio in the photosensitive conductive paste, followed by curing the obtained third mixture.

In the third mixture, the content of the photosensitive monomer is, for example, 30 wt % or more and 60 wt % or less (i.e., from 30 wt % to 60 wt %). In the third mixture, the content of the alkali-soluble polymer containing a cellulose derivative is, for example, 30 wt % or more and 60 wt % or less (i.e., from 30 wt % to 60 wt %). In the third mixture, the content of the photopolymerization initiator is, for example, 3 wt % or more and 10 wt % or less (i.e., from 3 wt % to 10 wt %). In the third mixture, the content of the organic flame retardant is, for example, 1 wt % or more and 30 wt % or less (i.e., from 1 wt % to 30 wt %).

Note that the present disclosure is not limited to the above-described embodiments, and can be changed in design without departing from the gist of the present disclosure.

### EXAMPLES

Hereinafter, the present disclosure will be described more specifically with reference to Examples. However, the present disclosure is not limited by the following Examples as a matter of course. It is also possible to appropriately modify and implement the present disclosure within a range applicable to the gist described above and below, and all of them are included in the technical scope of the present disclosure.

### Examples 1 to 7 and Comparative Examples 1 and 2

### (1) Preparation of Photosensitive Resin

Photosensitive resins A to H containing an organic component and a solvent were obtained by blending 25 wt % of a photosensitive monomer (dipentaerythritol hexa(meth)acrylate), 4 wt % of a photopolymerization initiator (α-aminoalkylphenone-based), 1 wt % of an antifoaming agent, an alkali-soluble polymer, a flame retardant, and the like at a blending ratio shown in Table 1, and sufficiently mixing the mixture. In Table 1, the balance of the formulation is a solvent (cyclohexanol acetate). Using each of the photosensitive resins A to H, the photosensitive conductive pastes of Examples 1 to 7 and Comparative Examples 1 and 2 were each prepared.

TABLE 1

| | Flame retardant | | Alkali-soluble polymer | | Others | |
|---|---|---|---|---|---|---|
| Photosensitive | | Content | | Content | | Content |
| resin | Type | (wt %) | Type | (wt %) | Type | (wt %) |
| A | Phosphoric acid | 5 | Carboxy group- | 30 | — | — |
| | ester | | containing acrylic | | | |
| | | | polymer | | | |
| B | Thioether | 5 | Carboxy group- | 30 | — | — |
| | | | containing acrylic | | | |
| | | | polymer | | | |
| C | Melamine | 5 | Carboxy group- | 30 | — | — |
| | cyanurate | | containing acrylic | | | |
| | | | polymer | | | |
| D | Hexabromobenzene | 5 | Carboxy group- | 30 | — | — |
| | | | containing acrylic | | | |
| | | | polymer | | | |
| E | Chlorinated | 5 | Carboxy group- | 30 | — | — |
| | paraffin | | containing acrylic | | | |
| | | | polymer | | | |
| F | — | — | Carboxymethyl | 30 | — | — |
| | | | cellulose | | | |
| G | Thioether | 5 | Carboxymethyl | 30 | — | — |
| | | | cellulose | | | |
| H | — | — | Carboxy group- | 30 | AI203 | 5 |
| | | | containing acrylic | | | |
| | | | polymer | | | |

### (2) Preparation of Photosensitive Conductive Paste

The photosensitive conductive paste for forming an internal electrode was obtained by blending 80 wt % of a conductive powder, 18 wt % of each of the photosensitive resins (A to H), and 2 wt % of a dispersant, and sufficiently mixing the mixture with a three roll mill. An Ag powder having an average particle diameter D50 of 2.0 μm was used for the photosensitive conductive pastes of Examples 1 to 7 and Comparative Example 1, and an Ag powder having an average particle diameter D50 of 0.8 μm was used for the photosensitive conductive paste of Comparative Example 2.

### [Evaluation]

### (1) Weight Loss Rate

The components other than the solvent and the antifoaming agent were mixed with the photosensitive resins A to H shown in Table 1 at the same ratio to obtain an organic component. The organic component was irradiated with ultraviolet rays to obtain a cured product. Using a thermogravimetric apparatus, ΔTG at 300° C. and 400° C. and the temperature T_{A100} when the weight was 100% decreased were measured for each cured product in an oxygen atmosphere.

### (2) Preparation and Measurement of Sample for Specific Resistance Evaluation

The photosensitive conductive paste was screen-printed and dried on an alumina substrate at a film thickness of 10 μm or more and 20 μm or less (i.e., from 10 μm to 20 μm), then exposed through a photomask having a wiring pattern, and developed with an alkaline aqueous solution to form a wiring pattern. The formed wiring pattern was fired at 900° C. for 60 minutes to produce an electrode wiring for resistance measurement. The resistance value, line width, line length, and film thickness of the obtained wiring sample were measured. The specific resistance value was calculated based on the Ag volume from the calculated volume of the wiring. Those having a specific resistance value of 2.2 μΩ·cm or less were rated as A (pass, good), and those having a specific resistance value exceeding 2.2 Ω·cm were rated as B (failed).

### (3) Preparation and Measurement of Sample for Firing Shrinkage Rate Evaluation

The photosensitive conductive paste prepared by the above method was printed on a smooth substrate, dried, then exposed through a photomask having a wiring pattern, and developed with an alkaline aqueous solution to form a wiring pattern. The volume of the wiring pattern of the obtained paste was calculated using a laser displacement meter. Next, these dot patterns were heat-treated at 700° C. The volume of the wiring pattern of the heat-treated sample was calculated again using a laser displacement meter. Based on the volume values before and after the heat treatment, what % the volume was reduced by the heat treatment was calculated, and this value was defined as the firing shrinkage rate.

In the heat treatment at 700° C., the photosensitive resins A to H were 100% decomposed. Typically, shrinkage of the element body 4, which does not contain an organic component, is small. Therefore, the photosensitive conductive paste (that is, internal electrode) has a small shrinkage rate after heat treatment at 700° C., which also indicates that delamination is suppressed.

Those having a shrinkage rate level of less than 30% at 700° C. were rated as A (pass, better), those having a level of 30% or more and less than 40% (i.e., from 30% to 40%) were rated as B (pass, good), and those having a level of 40% or more were rated as C (fail).

### (4) Patterning Property (Resolution Property)

The photosensitive conductive paste was screen-printed on an alumina substrate, and then dried at 60° C. for 30 minutes to form a photosensitive conductive paste film having a film thickness of 10 μm. Subsequently, the photosensitive conductive paste film was subjected to mask exposure treatment by irradiating the substrate with light rays from an ultra-high pressure mercury lamp (manufactured by Ushio Inc.) under the condition of 1000 mJ/cm² (405 nm) through a photomask having a linear pattern of L/S=25/25 μm. Thereafter, a development treatment was performed with a triethanolamine aqueous solution.

Those successfully formed a pattern without residue or line skipping were rated as A (pass), and those showed line skipping were rated as B (fail).

The evaluation results are shown in Table 2. In Table 2, the presence and absence of the flame retardant and the cellulose derivative are also shown.

TABLE 2

| | | | | | | | Firing | | |
|---|---|---|---|---|---|---|---|---|---|
| | | | | ΔTG | ΔTG | Temperature | shrinkage | | |
| | Photosensitive | Flame | Cellulose | (%) at | (%) at | (° C.) at | rate (%) | Specific | Patterning |
| | resin | retardant | derivative | 300° C. | 400° C. | ΔTG 100% | 700° C. | resistance | Property |
| Example 1 | A | Present | — | 34 | 59 | 550 | A | A | A |
| Example 2 | B | Present | — | 36 | 53 | 560 | A | A | A |
| Example 3 | C | Present | — | 41 | 41 | 545 | A | A | A |
| Example 4 | D | Present | — | 28 | 33 | 600 | A | A | A |
| Example 5 | E | Present | — | 31 | 42 | 600 | A | A | A |
| Example 6 | F | — | Present | 22 | 45 | 630 | A | A | A |
| Example 7 | G | Present | Present | 18 | 31 | 650 | A | A | A |
| Comparative | H | — | — | 33 | 44 | 640 | A | B | B |
| Example 1 | | | | | | | | | |
| Comparative | H | — | — | 45 | 57 | 590 | A | A | B |
| Example 2 | | | | | | | | | |

The photosensitive conductive paste of Examples satisfies the above conditions A and B, has a small firing shrinkage rate at a firing temperature of 700° C., and can be expected to suppress delamination. Furthermore, the photosensitive conductive paste used in Examples satisfies the above condition C, and the photosensitive conductive paste slowly shrinks until degreasing is completed, so that it can be expected that delamination is further suppressed.

In addition, since the photosensitive conductive paste of Examples does not contain a common material, the specific resistance after firing is small and the patterning property is good. Therefore, it can be seen that the electrical resistance is low, and the resolution in photolithographic patterning is improved.

On the other hand, since the photosensitive conductive paste of Comparative Example 1 did not contain a flame retardant and a cellulose derivative but contained a common material, the firing shrinkage rate at firing temperatures of 300° C. and 400° C. was small, but the specific resistance was large, and the patterning property was poor. Since the photosensitive conductive paste of Comparative Example 2 did not contain a flame retardant and a cellulose derivative but contained an Ag powder having a small particle size, the firing shrinkage rate at firing temperatures of 300° C. and 400° C. was small and the specific resistance was also small, but the patterning property was poor.
<1> A photosensitive conductive paste containing a conductive powder; an organic component; and a solvent. The organic component includes an alkali-soluble polymer, a photosensitive monomer, a photopolymerization initiator, and an organic flame retardant.
<2> A photosensitive conductive paste containing: a conductive powder; an organic component; and a solvent. The organic component includes an alkali-soluble polymer, a photosensitive monomer, and a photopolymerization initiator, and the photosensitive conductive paste contains a cellulose derivative as the alkali-soluble polymer.
<3> The photosensitive conductive paste according to <1>, containing a cellulose derivative as the alkali-soluble polymer.
<4> The photosensitive conductive paste according to <1> or <3>, in which the organic flame retardant includes at least one selected from the group consisting of a phosphoric acid ester compound, a thioether compound, a nitrogen-containing aromatic compound, a brominated hydrocarbon compound, and a chlorinated hydrocarbon compound.
<5> The photosensitive conductive paste according to <1>, <3>, or <4>, wherein the organic flame retardant includes at least one of a thioether compound and a chlorinated hydrocarbon compound.
<6> The photosensitive conductive paste according to any one of <2> to <5>, wherein the cellulose derivative has a water-soluble substituent.
<7> The photosensitive conductive paste according to any one of <1> to <6>, wherein a cured product of the organic component has a thermal decomposition ability in an oxygen atmosphere that satisfies a condition A and a condition B below.

### (Condition A)

In thermogravimetry, there is a weight loss rate of less than 50% at 300° C.

### (Condition B)

In thermogravimetry, there is a weight loss rate of 100% at 700° C.
<8> The photosensitive conductive paste according to <7>, in which, in the condition A, there is a weight loss rate of less than 30% at 300° C.
<9> The photosensitive conductive paste according to <7> or <8>, in which, in the condition B, there is a weight loss rate of 100% at 600° C.
<10> The photosensitive conductive paste according to any one of <7> to <9>, in which the cured product has a thermal decomposition ability in an oxygen atmosphere that satisfies a condition C below.

### (Condition C)

In thermogravimetry, there is a weight loss rate change of 70% or less in a range of 300° C. or higher and 400° C. or lower (i.e., from 300° C. to 400° C.).
<11> The photosensitive conductive paste according to any one of <1> to <10>, in which the conductive powder is a silver powder.
<12> The photosensitive conductive paste according to <11>, in which the silver powder has an average particle diameter D50 of 0.5 μm or more and 5.0 μm or less (i.e., from 0.5 μm to 5.0 μm).
<13> A method for producing a laminated electronic component, the method including laminating the photosensitive conductive paste according to any one of <1> to <12> on an insulating layer; and sintering the photosensitive conductive paste and the insulating layer at a firing temperature of 800° C. or higher. An internal electrode is formed from the photosensitive conductive paste, an element body is formed from the insulating layer, and the internal electrode is provided in the element body.
<14> A laminated electronic component including an element body containing a borosilicate glass and an inorganic filler; and an internal electrode that is provided in the element body and is a sintered body of the photosensitive conductive paste according to any one of <1> to <12>.

What is claimed is:

1. A photosensitive conductive paste comprising:
a conductive powder;
an organic component including an alkali-soluble polymer, a photosensitive monomer, a photopolymerization initiator, and an organic flame retardant; and
a solvent.

2. A photosensitive conductive paste comprising:
a conductive powder;
an organic component including an alkali-soluble polymer, a photosensitive monomer, and a photopolymerization initiator; and
a solvent,
wherein the alkali-soluble polymer includes a cellulose derivative.

3. The photosensitive conductive paste according to claim 1, wherein
the alkali-soluble polymer includes a cellulose derivative.

4. The photosensitive conductive paste according to claim 1, wherein
the organic flame retardant includes at least one selected from the group consisting of a phosphoric acid ester compound, a thioether compound, a nitrogen-containing aromatic compound, a brominated hydrocarbon compound, and a chlorinated hydrocarbon compound.

5. The photosensitive conductive paste according to claim 1, wherein
the organic flame retardant includes at least one of a thioether compound and a chlorinated hydrocarbon compound.

6. The photosensitive conductive paste according to claim 2, wherein
the cellulose derivative has a water-soluble substituent.

7. The photosensitive conductive paste according to claim 1, wherein
a cured product of the organic component has a thermal decomposition ability in an oxygen atmosphere that satisfies a condition A and a condition B below:
(Condition A)
in thermogravimetry, there is a weight loss rate of less than 50% at 300° C.; and
(Condition B)
in thermogravimetry, there is a weight loss rate of 100% at 700° C.

8. The photosensitive conductive paste according to claim 7, wherein
in the condition A, there is a weight loss rate of less than 30% at 300° C.

9. The photosensitive conductive paste according to claim 7, wherein
in the condition B, there is a weight loss rate of 100% at 600° C.

10. The photosensitive conductive paste according to claim 7, wherein
the cured product has a thermal decomposition ability in an oxygen atmosphere that satisfies a condition C below:
(Condition C)
in thermogravimetry, there is a weight loss rate change of 70% or less in a range of from 300° C. to 400° C.

11. The photosensitive conductive paste according to claim 1, wherein
the conductive powder is a silver powder.

12. The photosensitive conductive paste according to claim 11, wherein
the silver powder has an average particle diameter D50 of from 0.5 μm to 5.0 μm.

13. A method for producing a laminated electronic component, the method comprising:
laminating the photosensitive conductive paste according to claim 1 on an insulating layer; and
sintering the photosensitive conductive paste and the insulating layer at a firing temperature of 800° C. or higher,
wherein an internal electrode is formed from the photosensitive conductive paste,
an element body is formed from the insulating layer, and
the internal electrode is provided in the element body.

14. A laminated electronic component comprising:
an element body including a borosilicate glass and an inorganic filler; and
an internal electrode that is in the element body and is a sintered body of the photosensitive conductive paste according to claim 1.

15. The photosensitive conductive paste according to claim 3, wherein
the organic flame retardant includes at least one selected from the group consisting of a phosphoric acid ester compound, a thioether compound, a nitrogen-containing aromatic compound, a brominated hydrocarbon compound, and a chlorinated hydrocarbon compound.

16. The photosensitive conductive paste according to claim 3, wherein
the organic flame retardant includes at least one of a thioether compound and a chlorinated hydrocarbon compound.

17. The photosensitive conductive paste according to claim 3, wherein
the cellulose derivative has a water-soluble substituent.

18. The photosensitive conductive paste according to claim 2, wherein
a cured product of the organic component has a thermal decomposition ability in an oxygen atmosphere that satisfies a condition A and a condition B below:
(Condition A)
in thermogravimetry, there is a weight loss rate of less than 50% at 300° C.; and
(Condition B)
in thermogravimetry, there is a weight loss rate of 100% at 700° C.

19. The photosensitive conductive paste according to claim 2, wherein
the conductive powder is a silver powder.

20. A method for producing a laminated electronic component, the method comprising:
laminating the photosensitive conductive paste according to claim 2 on an insulating layer; and
sintering the photosensitive conductive paste and the insulating layer at a firing temperature of 800° C. or higher,
wherein an internal electrode is formed from the photosensitive conductive paste,
an element body is formed from the insulating layer, and
the internal electrode is provided in the element body.
